(19) United States
(12) Patent Application Publication
(10) Pub. No.: US 2004/0263203 A1
(43) Pub. Date: Dec. 30, 2004

(54) Signal compensation

(75) Inventor: Ana Luisa Lattes, Newton, MA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 10/608,632

(22) Filed: Jun. 27, 2003

(51) Int. Cl. H03K 19/003

(52) U.S. Cl. 326/30

(57) ABSTRACT

According to an embodiment of the invention, a method and apparatus for signal compensation are described. Under one embodiment, a driver comprises a resistance network having a plurality of legs; and a plurality of predriver circuits, each of the plurality of predriver circuits being associated with one of the plurality of legs of the resistance network. Each predriver circuit receives a first input to determine whether the predriver produces a signal and a second input to determine when to produce the signal.

### FIELD

An embodiment of the invention relates to electronic circuits in general, and more specifically to signal compensation.

### BACKGROUND

In electronic circuits, various signals may be driven onto a bus or other device. For this purpose, at chip interfaces generally there are specialized circuits known as I/O drivers. Among other features, I/O drivers are intended to match impedances and to control certain signal characteristics, such as slew-rate and timing. An I/O driver generally consists of an input receiver and an output driver, which generally consists of a predriver stage and a driver stage. The predriver stage may include logic control to manage operations, which may include slew-rate control and driver strength setting. The terms driver, I/O driver, and output driver may be used interchangeably.

However, process, voltage, or temperature (PVT) variations often modify the characteristics of circuits, resulting in significant changes in driver operations. As a result, a conventional I/O driver circuit may not provide acceptable operations in all conditions. If a conventional circuit or system is structured to attempt to provide compensation for signal operation in response to PVT changes, the circuit or system may then become unnecessarily complicated, or may provide operations that are less reliable than is desired.

### BRIEF DESCRIPTION OF THE DRAWINGS

The invention may be best understood by referring to the following description and accompanying drawings that are used to illustrate embodiments of the invention.

In the drawings:

FIG. 1 is a timing diagram illustrating possible signals produced by predrivers, with compensation for PVT variations being provided for impedance strength but not for slew-rate;

FIG. 2 is a simplified block diagram for one embodiment;

FIG. 3 is an illustration of a circuit in which variable delay is implemented using a passgate;

FIG. 4 is a flow chart illustrating operation of predriver;

FIG. 5 is a timing diagram illustrating possible signals produced by predrivers, with compensation for PVT variations being provided for impedance strength and slew-rate;

FIG. 6 is a block diagram of devices coupled with a bus; and

FIG. 7 is a block diagram illustrating an exemplary computer.

### DETAILED DESCRIPTION

A method and apparatus are described for provision of compensation for driven signals.

Terminology

Before describing an exemplary environment in which various embodiments of the present invention may be implemented, some terms that will be used throughout this application will briefly be defined:

As used herein, “driver” means a circuit that provides a signal to another circuit, including a circuit that provides or drives a signal on a bus.

As used herein, “PVT variations” means any variation in circuit processes, voltage levels, or temperature conditions for an integrated circuit or other electronic circuit.

As used herein, “buffer delay” means timing delay for a buffer or I/O driver, the value of which is expressed as Tᵥₐₗ.

As used herein, “buffer” means an isolating circuit or device. A buffer may comprise a circuit or device to amplify a signal for the purpose of driving a desired load.

As used herein, “edge-rate control” means control over the rising or falling of a signal. The terms “edge-rate” and “slew-rate” may be used interchangeably herein.

Signal Compensation

Under an embodiment of the invention, a circuit to drive signals includes the capacity to provide for signal compensation to respond to PVT variations with minimal logic requirements. Under an embodiment of the invention, the signal compensation improves buffer delay and edge-rate control. As shown herein, the operation may apply to a PCI (peripheral component interconnect) driver. However, the invention is not limited to such application and may be used in many different environments. Embodiments of the invention may be applied to any operation in which a signal is driven onto a bus or other similar process. In an implementation with a PCI bus, specific requirements for impedance, slew-rate, and buffer delay (Tᵥₐₗ) need to be met for proper operation. Under an embodiment of the invention, compensation is provided to improve buffer delay and edge-rate control for a PCI driver under varying PVT conditions in order to meet the operational requirements.

Under an embodiment of the invention, a resistor compensation circuit (RCOMP) is utilized. RCOMP circuits are widely used and commonly known, and thus are not discussed in depth herein. In this example, the RCOMP circuit is a separate unit which calculates the driver strength and sends the information to the IOs as RCOMP bits. The output transistors of the driver are legged in a linear manner and the predrivers turn on or off a certain number of legs to achieve desired driver impedance. Under a particular embodiment, pullup and pulldown devices for a driver are independent. In determining the number of legs for the driver, a balance may be made between minimizing the complexity of the driver and providing sufficient accuracy of compensation. Different applications have different accuracy requirements, which may affect the number of legs needed for the pullup and pulldown devices of the driver. An embodiment of the invention illustrated in this description is a device that comprises 15 legs, but any number of legs may be used. In addition, all legs can be identical, or can vary in strength. In the application illustrated here, the driver legs decrease in strength for the higher bits, so that turning on and off a leg to compensate for PVT variations modifies the previous driver strength by less than 10% regardless of the PVT conditions.

Under an embodiment of the invention, driver strength is modified using the RCOMP to adjust impedance. The multiple legs of the driver may be individually activated or deactivated to achieve a desired impedance. Under an embodiment of the invention, RCOMP information regarding which legs to activate or deactivate for particular conditions is then fed back to predriver circuits to provide signal delay adjustments that respond to changes in the PVT conditions. This operation is accomplished using minimal additional logic, while providing for excellent performance across varying PVT conditions.

In one example, pullup and pulldown signal operations for driving a signal are independent and a device consists of 15 legs. Certain of the legs may be active in all conditions, while other legs (which are referred to herein as “switchable legs”) are either active or inactive depending on the conditions. In a typical or average condition, approximately half the switchable legs of the device will be active. Under relatively fast conditions, fewer legs will be active, and under the fastest conditions, all switchable legs will be inactive. Under relatively slow conditions, more legs will be active, and under the slowest conditions, all switchable legs will be active. The number of switchable legs that are active or inactive may vary dynamically as conditions change.

Under an embodiment of the invention, in addition to modifying the number of legs that are active, the predriver circuits for the active legs will be turned on at varying times. To improve the slew-rate of a signal, the predriver circuits are staggered such that the different legs turn on after certain time intervals. In one embodiment, the driver comprises of 15 legs and the predriver circuits for the legs that are active (the always-active legs and the switchable legs that are currently active) turn on at five different times. However, any combination legs and time intervals may be used. The number of legs and the spacing of time intervals for the predrivers may be chosen to be large enough to be effective for a particular implementation, but small enough to simplify implementation of the circuit.

The longer the intervals in between the times that the predriver circuits are turned on, the slower the resulting slew-rate of the driver signal. A slower slew-rate is generally desirable to reduce system noise, but, for the purposes of maintaining smooth output waveforms, the time intervals cannot be arbitrarily large. For example, with data operations at a clock speed of 66 megahertz, the maximum interval between the time when the predriver of the earliest leg is turned on and the time when the predriver for the last leg is turned on should not exceed 1.5 nanoseconds. A slow slew-rate generally results in a slow driver with a large Tᵥₐₗ. For this reason, slew-rate and Tᵥₐₗ are balanced to meet required timing specifications, such as timing specifications for a PCI bus.

The number of time points for turning on predrivers can be smaller than the number of legs of the output driver, thus resulting in more than one leg turning on at the same time. In one embodiment, the driver comprises 15 legs, legs 0 through 14, and with 5 possible times for turning on the predriver circuits. In this example, the process may include turning on 3 legs after each time interval as provided in Table 1.

TABLE 1

| | Predriver for Legs |
|---|---|
| | Turned On |
| Time Interval | (If Leg is Active) |
| 1 | 14, 9, 4 |
| 2 | 13, 8, 3 |
| 3 | 12, 7, 2 |
| 4 | 11, 6, 1 |
| 5 | 10, 5, 0 |

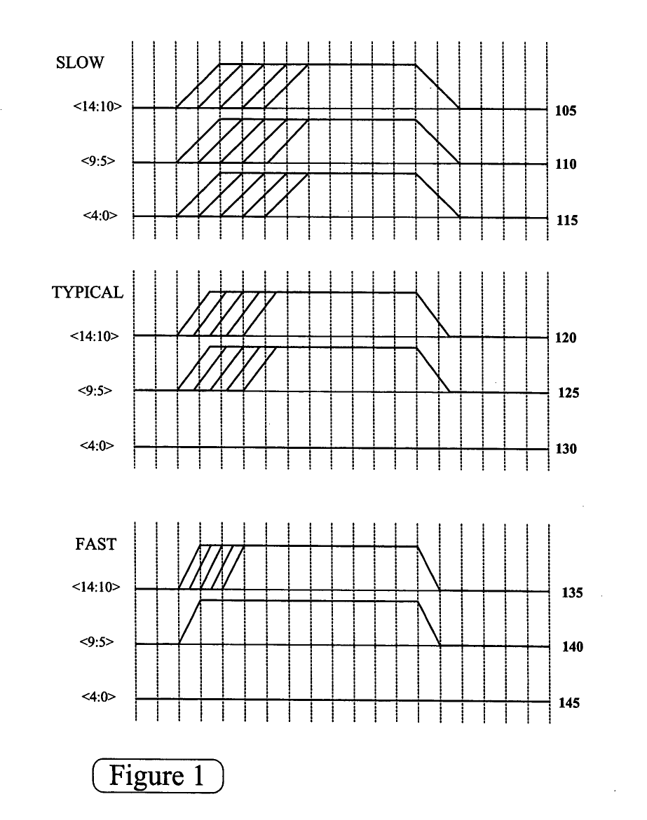

Signal timing for a particular embodiment of the invention, including 15 legs and 5 time points for turning on the legs, is illustrated in FIG. 1. FIG. 1 shows signal timing for pulldown impedance. Pullup impedance would be very similar, with the polarity of the signals being reversed. In this embodiment, the predriver signals are generated by predriver circuits, each of which consists of a pair of predrivers: predriver_xxx determines when each leg turns on, while predriver_yyy determines if each leg turns on. Under an embodiment of the invention, regardless of the timing for turning on each leg, all legs turn off at the same time to prevent excessive current load. In FIG. 1, the predriver signals for the 15 legs are turned on at 5 different time points as shown in Table 1. In this example, the predrivers for legs 14 through 9 are active in all cases. Legs 8 through 0 are switchable legs and may be either active or inactive, depending on the current PVT conditions.

Timing diagrams 105, 110, and 115 illustrate signal timing for slow conditions. Timing diagram 105 illustrates the predriver signal timing for legs 14 through 10, timing diagram 110 illustrates signal timing for legs 9 through 5, and timing diagram 115 illustrates signal timing for legs 4 through 0. The signals have been split into three timing diagrams to differentiate between the predrivers that are turned on at the same time, such as the predrivers for legs 14, 9, and 4. As shown in the timing diagrams, in slow conditions all of the legs are active.

Timing diagrams 120, 125, and 130 illustrate predriver signal timing for typical conditions, in which roughly half of the switchable legs will be active. Timing diagram 120 illustrates signal timing for legs 14 through 10, timing diagram 125 illustrates signal timing for legs 9 through 5, and timing diagram 130 illustrates signal timing for legs 4 through 0. In this example, legs 14 through 5 are active, while legs 4 through 0 are inactive.

Timing diagrams 135, 140, and 145 illustrate signal timing for fast conditions, in which fewer legs will be active. Timing diagram 135 illustrates signal timing for legs 14 through 10, timing diagram 140 illustrates signal timing for legs 9 through 5, and timing diagram 145 illustrates signal timing for legs 4 through 0. In this example, legs 14 through 9 are active, while all of the switchable legs (legs 8 through 0) are inactive.

In FIG. 1, PVT variations cause the time intervals between signals to be largest for the slow case and smallest for the fast case. This result is not optimal and can result in unacceptably slow (or fast) output delays (Tᵥₐₗ) and slew-rates for the slow (or fast) conditions. Under an embodiment of the invention, signal operations may be improved by utilizing RCOMP signals to adjust delay intervals. The RCOMP signals are thus utilized both to determine which legs are active and to modify the intervals between the times at which the predriver signals are turned on for the active legs. According to the embodiment, the RCOMP signals are used to generate time intervals that are shorter for slow conditions and are longer for fast conditions. The driver presented herein is simple and reliable, adjusting the signal compensation based on the already available RCOMP signals.

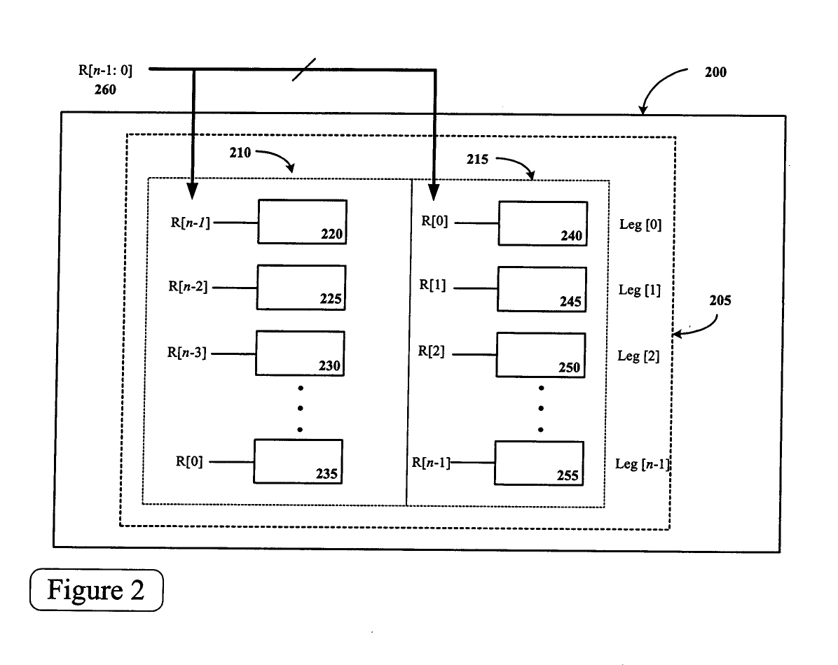

FIG. 2 illustrates one embodiment of the invention. The implementation shown in FIG. 2 is one possible example, but the logic for the circuit can be partitioned in numerous other ways. In this example, a driver circuit 200 comprises n legs, with n being any number greater than one. RCOMP signals are designated as R[0] through R[n−1] for the n legs. The driver circuit 200 includes a predriver 205 consisting of two circuits, predriver_xxx 210 and predriver_yyy 215. Predriver_xxx 210 determines the timing delays for signals that are produced. Predriver_xxx 210 consists of circuit blocks 220, 225, 230, continuing through circuit block 235, for a total of n circuit blocks for the n legs. Predriver_yyy 215 determines which legs are active, activating or deactivating legs to compensate for varying PVT conditions, with fewer legs activated for faster conditions and more legs activated for slower conditions. Predriver_yyy 215 comprises n circuit blocks for the n legs, the circuit blocks being shown as circuit blocks 240, 245, 250, continuing through 255.

The driver circuit 200 receives RCOMP signals 260, which indicate which of the output driver legs should be active at any time for the existing conditions. The value of RCOMP signals 260 is based on detection of the conditions for the circuit. As shown in FIG. 2, the signal is comprised of n bits designated as 0 through n−1. Each circuit block of predriver_xxx 210 receives an input associated with an output driver leg. The input to each circuit block of predriver_xxx 210 determines when each of the predriver signals turns on. As shown in FIG. 2, each predriver_xxx receives as an input a bit of RCOMP signals 260 for a different leg, with the legs matched in reverse order. Therefore, the first circuit block has the signal value for the last leg as an input. For example, circuit block 220 associated with Leg [0] receives R[n−1] for an input.

Predriver_yyy 215 determines which legs are active based on the RCOMP signals 260. Each circuit block of predriver_yyy 215 receives the associated signal for each leg. For example, circuit block 240 associated with Leg[0] receives R[0] as an input. Certain of the legs may be active at all times, which certain other legs are switchable and may be either active or inactive.

Each circuit block of predriver_xxx 210 institutes a signal delay and such delays determine the intervals between the times for turning on signals. A minimum delay will occur if the input to a circuit block is active and a maximum delay will occur if the input is inactive. Therefore, activating more legs, as in slower conditions, tends to result in reduced delays for the active legs, offsetting the slower conditions. Activating fewer legs, as in faster conditions, tends to result in increased delays, offsetting the faster conditions. For the example of circuit block 220, a signal will be produced with minimum delay if second input R[n−1] is off and will be produced with maximum delay if R[n−1] is on. Each of the other circuit blocks of predriver_xxx 210 operates in the same manner based on the input for each circuit block.

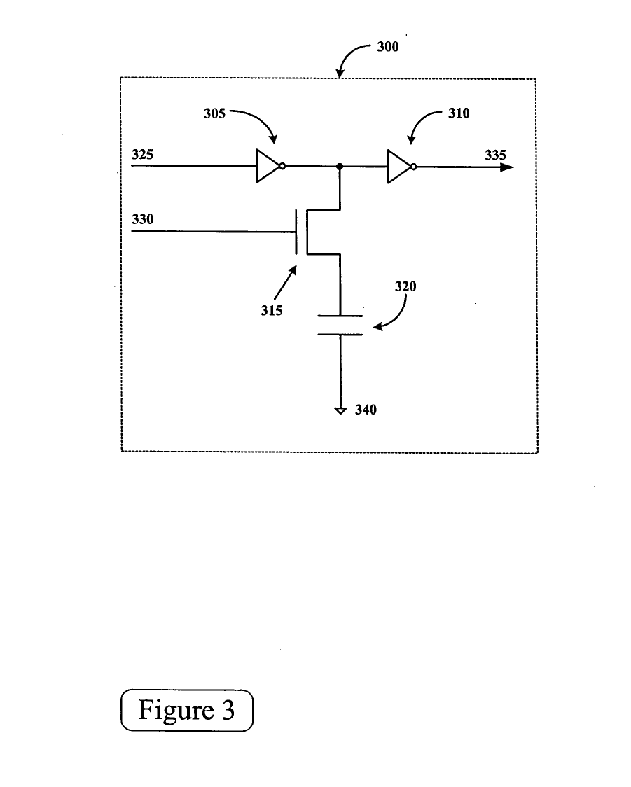

The intervals between the times that that predriver signals are turned on can be implemented in numerous ways. According to one embodiment of the invention, the predrivers of a driver are designed such that the time interval is varied by turning on and off a passgate connected to a load capacitor. FIG. 3 is an illustration of a circuit for predriver that contains a passgate according to an embodiment of the invention. FIG. 3 is a simplified illustration and does not contain all elements and connections that may be included in a circuit. In this illustration, the circuit 300 contains a first inverter 305 and a second inverter 310, the output of the first inverter 305 being coupled to the input of the second inverter 310. The output of the second inverter 310 is utilized in producing the output 335 of the circuit 300.

A first terminal of a passgate 315 is coupled to the output of the first inverter 305 and the input of the second inverter 310. A second terminal of the passgate 315 is connected to a first end of a load capacitor 320, with a second end of the load capacitor 320 being connected to ground 340. A first input 325 for the circuit 300 is received at the input to the first inverter 305. The first input 325 is a signal indicating whether the leg associated with the circuit is active. If the leg is inactive, the circuit will remain off. A second input 330 is received at the gate of the passgate 315, with the second input 330 being a signal that will determine the length of the time delay before turning on the predriver signal.

Under one particular embodiment of the invention, each leg receives a second input that is the corresponding signal for the legs of the in reverse order. For example, if the illustrated circuit 300 is associated with leg 14 of legs 14 through 0, then second input 330 is the signal for leg 0. If the second input 330 is a signal for a leg that is active, the path to the load capacitor 320 is cut off and the minimum signal delay will occur in the output 335. If the second input 330 is a signal for a leg that is inactive, the path to the load capacitor 320 is enabled and the maximum signal delay will occur in the output 335. The actual length of the time delays is dependent on the elements incorporated in the circuit.

For example, in fast conditions, lower-bit legs are inactive and the legs for higher-bit legs are active, adding delay to the higher bit legs. In the extreme case, where all the lower-bit legs are inactive and only the always-active legs are utilized, the passgates for the active higher-bit legs are on, thus resulting in all delays for active legs being of maximum length. This result assists in the fast case because it adds buffer delay, helping to meet the minimum Tᵥₐₗ, and slows the slew-rate, minimizing system noise. It is noted that in fast conditions the inactive lower bit legs have passgates that are turned off (because the higher bit legs are active), thus indicating minimum delay. However, the legs associated with these circuits are inactive and thus the passgates for these circuits, whether on or off, have no effect on the resulting signal.

In slow conditions, the results are reversed. In slow conditions, both higher-bit legs and lower bit legs are active, reducing the delay for active legs. In the extreme slow case in which all legs are active, all the passgates are off, thus resulting in all the delays being of minimum length. This result improves the signal operation in the slow case because there is improved Tᵥₐₗ and a faster slew-rate.

In the intermediate cases, some passgates for active legs will be on and some passgates for active legs will be off. As a result, the predriver signals for the active legs will turn on at correspondingly different times, some with minimum delay and some with maximum delay. The delays under these circumstances will average out to an intermediate value that is designed to be appropriate for typical conditions.

Therefore, an embodiment of a pre-driver can provide compensation for any PVT conditions, with the slew-rate being adjusted to offset timing changes. As the conditions result in faster operation, more legs are turned off, thereby resulting in greater delay and reducing the slew-rate. As the conditions result in slower operation, more legs are turned on, resulting in less delay and increasing the slew-rate. In addition to providing better slew-rate control, a pre-driver provides some compensation for the total buffer delay, resulting in a smaller Tᵥₐₗ range across PVT conditions. Further, the compensation occurs automatically based on the number of legs that are activated or deactivated for the current conditions, with only minimal logic required.

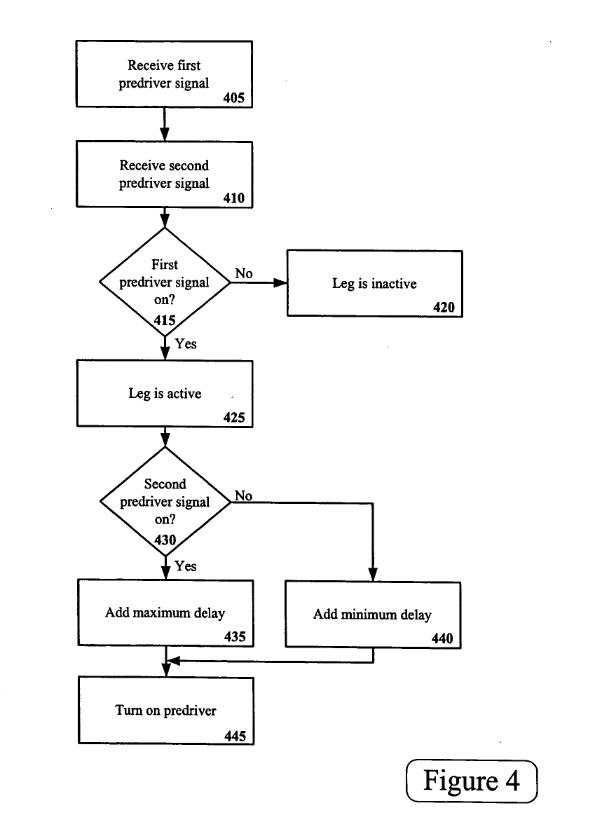

FIG. 4 is a flowchart illustrating the operation of each predriver circuit associated with a leg of a resistance network under an embodiment of the invention. Under the embodiment, a first predriver signal is received 405 and a second predriver signal is received 410. If the first signal is off 415, then the associated leg is inactive 420. If the first predriver signal is on 415, then the leg will be active 425. If the second predriver signal is on 430, then the signal for the leg is subject to maximum delay 435. If the second predriver signal is off 430, then the signal for the leg is subject to minimal delay 440. The signal is turned on 445 after the appropriate time interval.

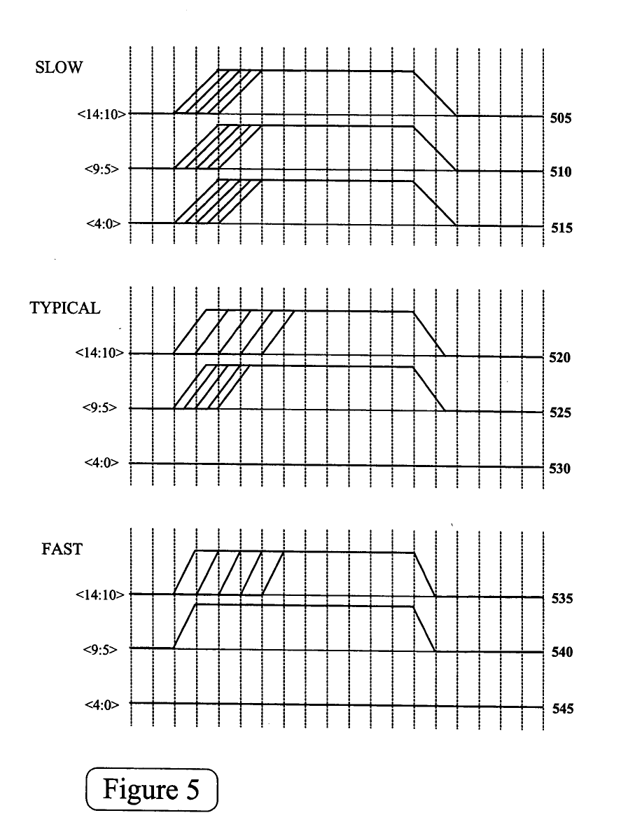

FIG. 5 includes timing diagrams illustrating signal timing under an embodiment of the invention utilizing an output driver with 15 legs and 5 possible delay intervals. In this illustration, the delay length is modified by utilizing information that controls which legs are active. The predriver circuits are connected such that each circuit receives the signal for the associated leg as a first input and a signal for a reverse ordered leg as a second input. Therefore, for example, the circuit associated with leg 14 receives the signal for leg 14 as a first input and the signal for leg 0 as a second input. Of the 15 legs, legs 14 through 9 are always active and legs 8 through 0 are switchable legs and may be active or inactive.

Signal timing in a slow condition is illustrated by timing diagram 505 illustrating the signal timing for legs 14 through 10, timing diagram 510 illustrating the signal timing for legs 9 through 5, and timing diagram 515 illustrating the signal timing for legs 4 through 0. In this illustration, under a slow condition, all 15 legs are active. In the slow case all 15 legs are turned on, thereby resulting in minimum delay for each predriver. The minimum delay thus provides compensation in the slow case, providing the least delay when the signal is the slowest.

Timing in a typical or average condition is illustrated by timing diagram 520 illustrating the signal timing for legs 14 through 10, timing diagram 525 illustrating the signal timing for legs 9 through 5, and timing diagram 530 illustrating the signal timing for legs 4 through 0. In this illustration, under the typical condition, legs 14 through 5 are active and legs 4 through 0 are inactive. With legs 4 through 0 inactive, maximum delay will result for the predriver circuits receiving these signals as a second input, the circuits being the circuits associated with legs 14 through 10 as shown in timing diagram 520. The delays for the signals for legs 9 through 5 remain at minimum delay, as shown in timing diagram 525, and legs 4 through 0 are inactive and thus the signals do not turn on, as shown in timing diagram 530. An intermediate result is produced for the typical or average condition, with half of the active legs producing signals with maximum delay and half of the active legs producing signals with minimum delay.

Timing in a fast condition is shown by timing diagram 535 illustrating the signal timing for legs 14 through 10, timing diagram 540 illustrating the signal timing for legs 9 through 5, and timing diagram 530 illustrating the signal time for legs 4 through 0. In this illustration, under fast conditions, legs 14 through 9 are active and legs 8 through 0 are inactive. With legs 8 through 0 inactive, maximum signal delay will result for the circuits receiving these signals as a second input, these circuits being the circuits associated with all of the active legs, legs 14 through 9. This is shown in timing diagram 535 and timing diagram 540. The signals for legs 8 through 0 do not turn on, as shown in timing diagrams 540 and 545. The maximum delay thus provides compensation in the fast case, providing the greatest delay when the signal is the fastest.

Alternative Embodiments

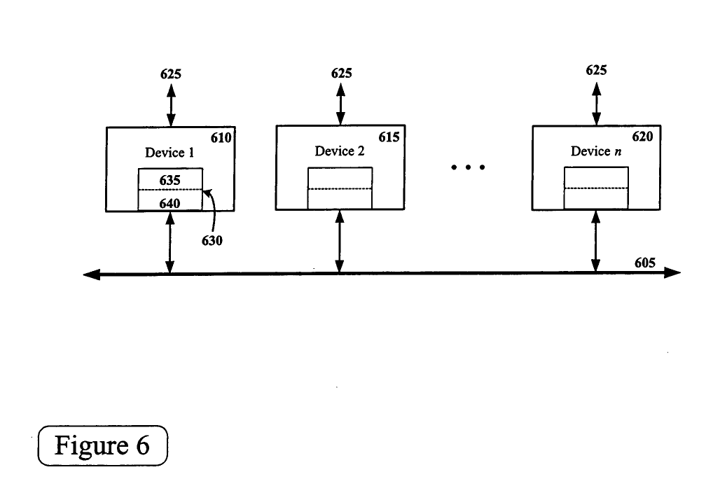

Techniques described here may be used in many different environments. For example, FIG. 6 is a block diagram of devices coupled to a bus that may utilize embodiments of the invention. The devices may utilize embodiments of the invention. In this example, one or more devices are coupled to a bus 605, the devices being illustrated as device 1 610, device 2 615, and continuing through device n 620. The devices may include many different types of devices, including, but not limited to, network processors, network routers, and other similar units. Each device may have additional connections to one or more other buses or devices 625. In this example, device 1 610 includes an I/O driver 630, which includes a predriver stage 635 and a driver stage 640. Under an embodiment of the invention, the I/O driver 630 provides for compensation for varying PVT variations.

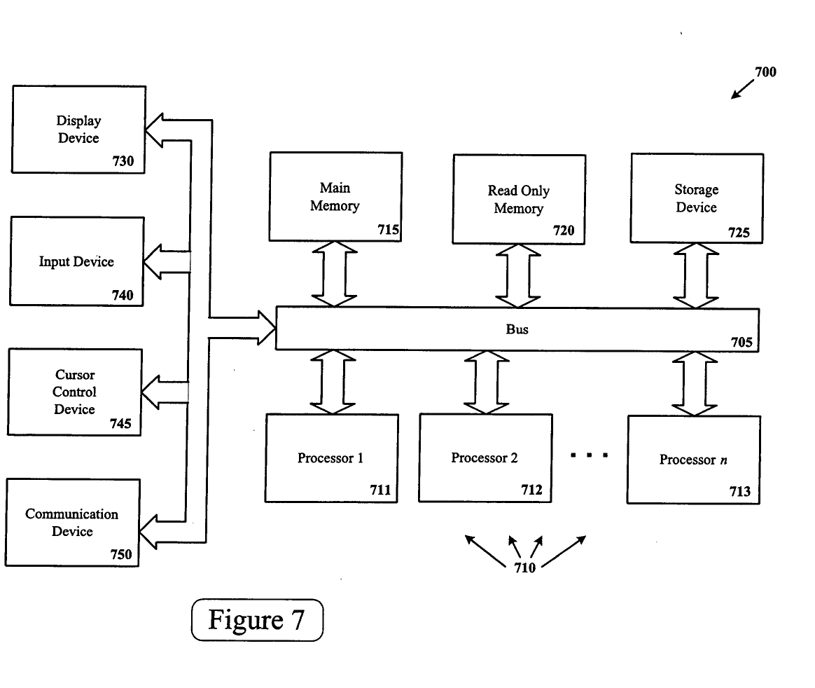

As an additional example, FIG. 7 is a block diagram of an exemplary computer. Under an embodiment of the invention, a computer 700 comprises a bus 705 or other communication means for communicating information. Among other possible uses, an embodiment of the invention may be incorporated in a device that is coupled to the bus 705. In this illustration, a processing means such as processors 710 are coupled with the bus 705 for processing information. The processors 710 are shown as processor 1 711, processor 2 712, and continuing through processor n 713, but may include any number of processors. The computer 700 further comprises a random access memory (RAM) or other dynamic storage device as a main memory 715 for storing information and instructions to be executed by the processors 710. Main memory 715 also may be used for storing temporary variables or other intermediate information during execution of instructions by the processors 710. The computer 700 also may comprise a read only memory (ROM) 720 and/or other static storage device for storing static information and instructions for the processors 710.

A data storage device 725 may also be coupled to the bus 705 of the computer 700 for storing information and instructions. The data storage device 725 may include a magnetic disk or optical disc and its corresponding drive, flash memory or other nonvolatile memory, or other memory device. Such elements may be combined together or may be separate components, and utilize parts of other elements of the computer 700.

The computer 700 may also be coupled via the bus 705 to a display device 730, such as a liquid crystal display (LCD) or other display technology, for displaying information to an end user. In some environments, the display device may be a touch-screen that is also utilized as at least a part of an input device. In some environments, display device 730 may be or may include an auditory device, such as a speaker for providing auditory information. An input device 740 may be coupled to the bus 705 for communicating information and/or command selections to the processors 710. In various implementations, input device 740 may be a keyboard, a keypad, a touch-screen and stylus, a voice-activated system, or other input device, or combinations of such devices. Another type of user input device that may be included is a cursor control device 745, such as a mouse, a trackball, or cursor direction keys for communicating direction information and command selections to processors 710 and for controlling cursor movement on display device 730.

A communication device 750 may also be coupled to the bus 705. Depending upon the particular implementation, the communication device 750 may include a transceiver, a wireless modem, a network interface card, or other interface device. The computer 700 may be linked to a network or to other devices using the communication device 750, which may include links to the Internet, a local area network, or another environment.

General Matters

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

The present invention may include various steps. The steps of the present invention may be performed by hardware components or may be embodied in machine-executable instructions that may be used to cause a general-purpose or special-purpose processor or logic circuits programmed with the instructions to perform the steps. Alternatively, the steps may be performed by a combination of hardware and software.

Many of the methods are described in their most basic form, but steps can be added to or deleted from any of the methods and information can be added or subtracted from any of the described messages without departing from the basic scope of the present invention. It will be apparent to those skilled in the art that many further modifications and adaptations can be made. The particular embodiments are not provided to limit the invention but to illustrate it. The scope of the present invention is not to be determined by the specific examples provided above but only by the claims below.

It should also be appreciated that reference throughout this specification to “one embodiment” or “an embodiment” means that a particular feature may be included in the practice of the invention. Similarly, it should be appreciated that in the foregoing description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims are hereby expressly incorporated into this description, with each claim standing on its own as a separate embodiment of this invention.

What is claimed is:

1. A driver comprising:
a resistance network comprising a plurality of legs; and
a plurality of predriver circuits, each of the plurality of predriver circuits being associated with one of the plurality of legs of the resistance network, each predriver circuit receiving a first input to determine whether the predriver produces a signal and a second input to determine when to produce the signal.

2. The driver of claim 1, wherein the first input indicates whether the associated leg of the resistance network is active.

3. The driver of claim 2, wherein the second input to the predriver circuit indicates whether one of the plurality of legs of the resistance network is active.

4. The driver of claim 3, wherein the legs of the resistance network are in a certain order and wherein the second input for each predriver circuit is an input for a leg of the resistance network matched in a reversed order.

5. The driver of claim 3, wherein if a predriver circuit produces a signal:
the predriver circuit produces the signal after a first time interval if the second input to the predriver circuit indicates that the relevant leg is active; and
the predriver circuit produces after a second time interval if the second input to the predriver circuit indicates that the relevant leg is inactive.

6. The driver of claim 5, wherein slower conditions result in more active legs producing signals using a shorter time interval.

7. The driver of claim 5, wherein faster conditions result in more of the legs that are active producing signals using a longer time interval.

8. The driver of claim 1, wherein a predriver circuit comprises a passgate and a capacitor.

9. The driver of claim 8, wherein the second input to the predriver circuit is applied to the passgate, the second input determining whether the passgate opens or closes a path to the capacitor.

10. A method comprising:
receiving a first input and a second input for each of a plurality of signals, wherein:
the first input for each of the plurality of signals indicates whether a resistance associated with the signal is active, the resistance comprising one leg of a resistance network, the resistance network comprising a plurality of legs, and
the second input indicates whether one leg of the plurality of legs of the resistance network is active;
determining whether to produce each signal based at least in part on the first input for the signal; and
determining when to produce each signal based at least in part on the second input for the signal.

11. The method of claim 10, wherein the legs of the resistance network are in a certain order and wherein the second input for each signal is matched in reverse order.

12. The method of claim 10, wherein determining whether to produce each signal comprises producing a signal if the first input for the signal indicates that the resistance associated with the signal is active.

13. The method of claim 10, wherein determining when to produce each signal comprises choosing to produce a signal after a first delay if the second input for the signal is active and choosing to produce the signal after a second delay if the second input for the signal is inactive.

14. The method of claim 13, wherein determining when to produce the signal comprises choosing to produce the signal after a shorter delay in slow conditions and choosing to produce the signal after a longer delay in fast conditions.

15. A device comprising:
an interface to a bus; and
an I/O driver circuit to drive signals on the bus, the I/O driver comprising:
a driver section; and
a predriver section comprising:
a resistance compensation network comprising a plurality of legs, and
a plurality of predriver circuits, each predriver circuit being associated with one of the plurality of legs, each predriver circuit receiving a first input to determine if the predriver circuit produces a signal and a second input to determine the predriver circuit produces a signal.

16. The device of claim 15, wherein the first input to a predriver circuit indicates whether the associated leg of the resistance compensation network is active.

17. The device of claim 16, wherein the second input to a predriver circuit indicates whether one of the legs of the plurality of legs of the resistance network is active.

18. The device of claim 17, wherein the legs of the resistance network have a certain order and wherein the second input for each predriver circuit is an input for a leg of the resistance network matched in a reverse order.

19. The device of claim 17, wherein if a predriver circuit produces a signal:
the predriver circuit produces the signal after a first delay if the second input to the predriver circuit indicates that the relevant leg is active; and
the predriver circuit produces the signal after a second delay if the second input to the predriver circuit indicates that the relevant leg is inactive.

20. The device of claim 19, wherein if PVT (process, voltage, or temperature) conditions for the device result in slower operation, more of the active predriver circuits produce signals after a shorter delay.

21. The device of claim 20, wherein if PVT conditions for the device result in faster operation, more of the active predriver circuits produce signals after a longer delay.

22. The device of claim 15, wherein each predriver circuit comprises a passgate and a capacitor.

23. The device of claim 22, wherein the second input determines whether the passgate opens or closes a path to the capacitor.

24. A system comprising:
a processor;
a bus;
a driver to drive signals on the bus, the driver comprising:
a resistance network comprising a plurality of legs; and
a plurality of predriver circuits, each of the plurality of predriver circuits being associated with one of the plurality of legs of the resistance network, each predriver circuit receiving a first input to determine whether the predriver produces a signal and a second input to determine when to produce the signal.

25. The system of claim 24, wherein the first input to a predriver circuit indicates whether the associated leg of the resistance network is active.

26. The system of claim 25, wherein the second input to the predriver circuit indicates whether one of the plurality of legs of the resistance network is active.

27. The system of claim 26, wherein the legs of the resistance network are in a certain order and wherein the second input for each predriver circuit is an input for a leg of the resistance network matched in a reversed order.

28. The system of claim 26, wherein if a predriver circuit produces a signal:
the predriver circuit produces the signal after a first time interval if the second input to the predriver circuit indicates that the relevant leg is active; and
the predriver circuit produces after a second time interval if the second input to the predriver circuit indicates that the relevant leg is inactive.

29. The system of claim 24, wherein a predriver circuit comprises a passgate and a capacitor.
